(19) United States
(12) Patent Application Publication
(10) Pub. No.: US 2015/0299844 A1
(43) Pub. Date: Oct. 22, 2015

(54) Method for producing protective layers containing silicides and/or oxidized silicides on substrates

(71) Applicants: 2h.system, Mauren (LI); 3H GmbH Raum-Management-Systeme, Oppenweiler (DE)

(72) Inventors: Hans-Jürg Kessler, Ebmatingen (CH); Martin Demuth, Mülheim an der Ruhr (DE)

(21) Appl. No.: 14/415,144

(22) PCT Filed: Jul. 17, 2013
(86) PCT No.: PCT/DE2013/100264

§ 371 Date: Jun. 3, 2015

(30) Foreign Application Priority Data
Jul. 18, 2012 (DE) 10 2012 106 518.7

(51) Int. Cl. C23C 14/34; C23C 16/44; C23C 14/22; B05D 3/00; C01B 21/068; H01M 8/02; C25B 11/04; C25B 11/12; C01B 33/06; C01B 31/36; B05D 1/04; H01L 31/0216

(52) U.S. Cl. CPC C23C 14/34; B05D 1/04; C23C 16/44; C23C 14/22; B05D 3/007; H01L 31/02167; H01M 8/0271; C25B 11/0405; C25B 11/12; C01B 33/06; C01B 31/36; C01B 21/068

(57) ABSTRACT

The invention relates to a method for producing protective layers containing silicides and/or oxidized silicides on a substrate, in which silicide or a precursor thereof is applied to the substrate and the coated substrate is subjected to a temperature treatment above 250° C. without further processing. The layers obtained have a thickness in the nano-range and can simultaneously have various characteristic features, i.e. they are multifunctional. The following characteristic features were found for these nanolayers: scratch resistance, abrasion resistance, corrosion resistance and temperature resistance up to 1500° C., depending in each case on the substrate and the silicide(oxide) used for the coating.

The present invention concerns a method for producing protective layers of silicides and/or oxidized silicides on a substrate, in which silicides or a precursor thereof is applied onto the substrate and the coated substrate is subjected to a heat treatment; a high-strength silicide coating on a substrate obtained by the method according to the invention; and the use of the silicide coating.

The production and application of protective layers with comparable multi-functional properties as achievable with silicides are not known. Usually, these are thick layers far above 1,000 nanometers (nm) that, for the purpose of hardening, require long and thus uneconomical tempering times at high temperatures. When using these protective layers, singular properties are utilized wherein in particular scratch resistance is important. For this purpose, layers are also produced and used that are based on the use of plastic materials and are referred to as self-healing. The service life of such coatings is however limited. Thick layers have generally the disadvantage that they are not break-proof with respect to bending and to temperature fluctuations. Great temperature fluctuations effect chipping (off) of the layer due to different expansion coefficients of substrate and coating.

It has now been surprisingly found that the aforementioned disadvantages and limitations can be avoided by using thin silicide layers (nano layers) after short tempering for hardening of the layer with exclusion of oxygen. The exclusion of oxygen can be achieved by using a vacuum and/or using inert gases, for example, argon, nitrogen etc.

Object of the present invention is therefore a method for producing protective layers, containing silicides and/or oxidized silicides, on a substrate, in which silicide or a precursor thereof is applied onto the substrate and the coated substrate, without further processing, is subjected to a heat treatment above 250° C.

The obtained silicide layers exhibit the advantageous properties of the respectively employed silicide, such as scratch resistance, abrasion resistance, corrosion resistance, and temperature resistance up to 800° C.-1,500° C. Moreover, these nano layers are mostly semiconducting, water-repellant as well as dirt-repellant, light-resistant, marginally light-reflecting, and result in a high light transparency. They can be light-amplifying or light-absorbing, break-proof and also variably colored. Moreover, some nano silicide layers are stable in acids and bases in the total pH range of 1-14. They exhibit primarily excellent thermal as well as electric conductivity and are impermeable with regard to gas diffusion, in particular relative to oxygen, so that oxidation of the substrate/carrier material is inhibited.

Substrate means any material in any shape, even an already shaped component or workpiece or piece of material that is still to be deformed, bent or processed in any other way.

The application of the silicides or their precursors is carried out with methods known to a person of skill in the art, such as PVD (physical vapor deposition), CVD (chemical vapor deposition), electrostatic methods and/or screen printing. Preferably, the silicide particles are applied by means of cathode evaporation (sputter coating).

The invention encompasses a method for treating and conserving surfaces that are of metallic as well as of non-metallic nature. For this purpose, a protective nano layer of silicides is applied.

Silicides are to be understood as pure silicides as well as their oxides as well as mixtures of silicides and oxidized silicides.

The employed silicides are preferably selected from metal silicides, non-metallic silicides and/or nitrosilicides of the general formulas

Meₓ Si_{y} (1)

wherein Me means boron, nitrogen or a metal and x is a number from 1 to 6 and y is a number from 1 to 4, wherein it is not required that x and y be integers;

Me_{x′}Si_{y′}C_{z′} (2)

wherein Me has the aforementioned meaning and x′ is a number from 1 to 3 and y′ is a number from 1 to 4, z′ is a number from 1 to 4, wherein it is not required that x′, y′ and z′ be integers;

Siₐ C_{b} (3)

wherein a is a number between 1 and 2 and b is a number between 1 and 2; and precursors of silicides such as

Siₑ R₂ₑ₊₂ (4)

wherein R is an organic, metallic, organometallic, or inorganic residue or a mixture thereof, and e is a number from 1 to 4,
as well as oxidized silicides with the formulas (1) to (4) and mixtures of silicides and oxidized silicides.

As suitable examples of silicides the following can be mentioned: boron silicides, carbon-containing silicides, and nitrogen-containing silicides, such as e.g. titanium silicides (TiSi₂, Ti₅Si₃), nickel silicide (Ni₂Si), iron silicides (FeSi₂, FeSi), thallium silicide (ThSi₂), boron silicide, also referred to as silicon tetraboride (B₄Si), cobalt silicide (CoSi₂), platinum silicides (PtSi, Pt₂Si), manganese silicide (MnSi₂), titanium carbosilicide (Ti₃C₂Si), carbosilicide/poly-carbosilicide (CSi/poly-CSi), also referred to as silicon carbide/poly-silicon carbide, iridium silicide (IrSi₂), nitrosilicide, also referred to as silicon nitride (N₄Si₃), zirconium silicide (ZrSi₂), tantalum silicide (TaSi₂), vanadium silicide (V₂Si), or chromium silicide (CrSi₂), i.e., compounds that contain silicon and correspond to the molecular formula SiₑR₂ₑ₊₂ in which R is H or an organic, metallic, organometallic or inorganic residue or a mixture thereof, wherein R within a molecule can have different meanings, i.e, Si can have several substituents that are different among each other. The elementary compositions (molecular formulas) are exemplary and the ratios of the elements relative to each other are variable.

Moreover, it was found that the aforementioned properties of the silicide layers can be enhanced by doping with lithium, sodium, magnesium, potassium, calcium, aluminum, boron, carbon, nitrogen, silicon, titanium, vanadium, zirconium, yttrium, lanthanum, nickel, manganese, cobalt, gallium, germanium, phosphorus, cadmium, arsenic, technetium, α-SiH, and the lanthanides.

The application of the silicides different substrate/carrier materials results in high-strength protective layers which already for layer thicknesses in the range below 1,000 nm, but even already for very minimal layer thickness (10-500 nm), surprisingly exhibit several of the aforementioned characteristic properties simultaneously. Accordingly, multi-functional nano layers can be produced which, as a result of the employed minimal layer thicknesses, result in moderate production costs (coating and hardening process). The characteristic properties of the nano silicide layers are usually achieved by treatment at high temperatures, also referred to as tempering, usually above 250° C. Tempering is preferably carried out at temperatures between 250° and 1,000° C. The temperature should be adjusted to the heat resistance of the substrate to be coated; for example, the heat treatment for substrates of plastic materials is preferably at temperatures of 250° C. to 600° C. and for substrates of metal or high temperature-resistant other materials above 750° C. Tempering is realized according to the invention immediately following the coating step, i.e., without the fresh coating being subjected to additional method steps. This method step is preferably done with exclusion of oxygen and addition of inert gases.

The silicides are predominantly easily oxidizable; this is true in particular for the silicides having been coated by means of PVD and electrostatic coating because they are produced in amorphous form. Already in the presence of minimal quantities of oxygen, in particular when in contact with air, oxidized silicides are formed. The formation of such oxides is partially desired; in this way passivated silicide oxide layers are formed.

A coating that contains minimal quantities of oxidized silicides can also be obtained when already partially oxidized silicides are used for the coating step.

Tempering is carried out over a time period until complete curing of the coating has occurred, usually from one minute to 60 minutes, preferably from 5 minutes to 45 minutes. Subsequently, the coated substrate is allowed to cool to room temperature. Usually, cooling is done under inert gas. Cooling is preferably done slowly in order to avoid that stress is produced in the substrate due to a fast temperature change. The temperature course for cooling is preferably adjusted to the temperature behavior of the coated substrate.

For producing surface-oxidized nano silicide layers, after the tempering process cooling is carried out slowly, but in a range of 40-60° C. the inert gas is entirely or partially replaced with air. In this way, a partially oxidized coating can be obtained. By x-ray structure analysis it was determined that the thus generated passivated silicide oxide layer has a layer thickness of a few nanometers.

The aforementioned properties can be utilized in applications as a coating of polymer materials such as plastic materials, on glass materials or glass-like materials as well as metals and ceramics.

In a preferred embodiment, the substrate is selected from silicate-containing materials, such as glass, glass-like materials, ceramics, precious stones, metals, including noble metals and transition metals, metal oxides, plastic materials, and also graphite and similar materials.

In a possible embodiment, the substrate and the applied silicide are matched to each other such that the substrate and silicide contain identical elements. When as the substrate, for example, a metal A is coated, preferably a silicide of A or a precursor thereof is used as silicide or, when a mixture of silicides is used, a certain proportion is the silicide of A. When coating glass or silicate-containing substrates, silicon carbide and silicon nitride or a mixture of silicon carbide and silicon nitride has been found to be a suitable coating agent.

The adhesion of the coating according to the invention can be improved when intermediate layers, comprised of a metal such as aluminum or a transition metal, are applied with a layer thickness between 5 and 20 nm, preferably between 5 and 10 nm. For such intermediate layers, chromium, titanium, aluminum, and other metals as well as transition metals have been found to be suitable.

The application of the intermediate layer has been found to be suitable in particular when coating plastic materials.

Up to now, in connection with coatings with silicides the possibility of simultaneously utilizing all or most of the characteristic properties had not been recognized. Also, silicide layers with minimal layer thickness below 1,000 nm (nano layers) have not been used for practical application.

Moreover, it has been found that for the afore described coatings and applications the silicides can be used individually or in combination of two or more silicides and their oxides as well as of non-silicide layers.

This new technology, based on nano silicide coatings, can be used in the following applications: novel heating system, aviation and automotive technology, in the optical and metallurgical field for producing corrosion-resistant and scratch-resistant surfaces, as well as in combination with noble metals for reducing/preventing oxidation and wear of the surface and also for coating materials for electrolysis and similarly proceeding processes (for example, electrodes for the electrochemical splitting of water with light to hydrogen and oxygen and for the fuel-cell technology). Also, applications of the nano silicide coatings for reflective materials such as (solar) mirrors and reflectors are possible.

A further object of the present invention is a substrate with a high-strength silicide coating obtained by coating a substrate with a silicide or a precursor thereof according to the method according to the present invention.

Another further object of the invention concerns the use of the high-strength silicide coating or the substrate coated therewith in photovoltaics as cover layers, intermediate layers or depletion layers in the configuration of modules with improved light absorption and thus increased efficiency as well as for applications in fuel-cell technology and in photoelectrochemical water splitting for generating hydrogen and oxygen. Moreover, as a result of the minimal layer thickness and strength of the obtained coating, they are suitable as a protective layer for bendable substrates/carrier materials.

Definitions

Photovoltaics means the direct conversion of light into electrical energy.

So-called water splitting comprises a conversion of water into its elemental components hydrogen (H₂) and oxygen (½ O₂), for example, with light in the presence of a catalyst, such as e.g. a silicide, wherein the produced hydrogen can serve as a future and alternative energy source.

In fuel-cell technology, the reversal of water splitting is effected and electrical energy and water is produced from hydrogen and oxygen on a catalyst.

Silicides are chemical compounds that contain at least one silicon atom which has a greater electron density than elemental silicon. The application of silicides and oxides thereof on substrates, for example, glass, plastic materials, ceramics, and metals etc., results in protective silicide layers on these materials.

Nano coating or nano layers with silicides are layers which can be produced with silicide materials and particles thereof having minimal nanometer size.

Electrode coating is used for technologies of photovoltaics and of water splitting, i.e., for methods that require current flow (so-called electrochemical conversions). The current flow is generated between electrodes that are electrically conducting and are connected by an electrically conducting medium.

High-strength layers means that the coatings with silicides on substrates such as e.g. glass, plastic materials, and metals etc. have the aforementioned characteristic properties as mentioned before on page 2.

Layer Formation/Method Steps
1. The nano coatings are applied by means of the silicides as nanoparticles in pure form but also as silicide mixtures.
2. This is done by use of PVD (physical vapor deposition), CVD (chemical vapor deposition) and (pulsed) electrostatic coating methods.
3. It is important to clean the surface areas of the surfaces to be coated of the substrates/carrier materials prior to coating (for example, with hexane, toluene, isopropanol etc.).
4. The freshly coated material is tempered at temperatures of 250-600° C. and above 750° C. for hardening the coating during 5-45 minutes and subsequently cooled slowly to room temperature, depending on the respectively employed carrier materials, layer thicknesses, and type of the employed silicides. In case of use of plastic materials as carrier material, processing is done at a temperature as low as possible.
5. The nano layers can be applied alone or as a composite of several silicide layers as well as of non-silicide layers.
6. For improved adhesion on the surface to be coated, metallic intermediate nano layers (e.g. chromium, titanium, aluminum and other metals as well as transition metals) can be applied in a layer thickness of a range of 5-10 nanometers.
7. Since silicide/oxide coatings may be exposed to stronger mechanical loading, it is important to apply the nano coating as homogeneously as possible in order to avoid a future detachment/breaking of the layer.
8. In this way, multi-functional nano coatings are produced that primarily have primarily have simultaneously the characteristic properties indicated on page 2.

### EXAMPLES

### Example 1

A copper plate is coated with copper silicide (CuSi as target). For this purpose, the copper plate is first cleaned with isopropanol so that the ions of the sputtered copper silicide dock on the copper and not on foreign particles. With the sputtered copper silicide layer (nano layer, sputtering time 3 minutes) of 30-50 nm, the surface of the copper plate becomes scratch-resistant, oxidation-resistant as well as dirt-repellant and water-repellent without exhibiting loss of electrical conductivity.

Instead of coating by means of PVD, pulsed electrostatic coating technology can be used also.

### Example 2

Glass plates (sheet glass and quartz glass) are coated with silicon carbide (SiC as target). For this purpose, the glass plates are in advance cleaned with isopropanol and toluene so that the sputtered silicon carbide will not dock on foreign particles. With the silicon carbide sputtered on in a range of 20-40 nm, the surface of the glass plate becomes scratch-resistant and absorbs at the same time the incident light up to 80-90%, depending on the layer thickness (measurements by means of connected measuring device). In case of a layer thickness of 100 nm, a yellow tinge is achieved and for 200-300 nm the latter changes to a brown tinge (result from experiments). The glass plates coated by means of PVD (physical vapor deposition) are tempered for hardening the coating at 250-600° C. and preferably above 750° C., depending on the property of the carrier material, during 5-45 minutes and subsequently cooled slowly to room temperature.

### Example 3

Was carried out in analogy to example 2 but the glass surface is coated with silicon nitride (e.g. N₄Si₃) and silicon carbide (SiC), both present as target, respectively, and coated alternatingly in combination. In this way, a higher light transparency is achieved in comparison to example 2 which uses exclusively SiC. When exclusively silicon nitride is used for coating, a highly transparent and color-free nano layer (layer thickness 40-60 nm) with the aforementioned characteristic properties is obtained after tempering at 840° C. and slow cooling.

### Example 4

In analogy to the examples 2 and 3, electrode materials such as titanium and graphite were coated with SiC and silicon nitride (e.g., 200-300 nm layer thickness) and used as electrodes for photoelectrolytic splitting of water to hydrogen and oxygen. No wear of the electrode for months was observed; this for use of electrolyte solutions in the range of pH 1-14.

Analogous coatings are suitable for applications in fuel cell technology wherein the coating can be applied also by screen printing (layer thicknesses of 400-1,000 nm).

### Example 5

Plastic films (e.g., Teflon) were coated successfully with SiC/silicon nitride in analogy to the examples 2 and 3, wherein nano layers of a layer thickness 20-40 nm were applied and tempered at 250° C. and subsequently cooled slowly to room temperature. For improved adhesion of the coating on the plastic surface, an intermediate layer with chromium was sputtered on (approximately 5-10 nm).

### Example 6

In analogy to examples 3 and 5, coating was carried out by means of PVD but, in the range of 40-60° C. during the cooling process, the inert gas was replaced with air. In this way, by passivating oxidation by means of (air) oxygen, partially oxidized nano silicide coatings of a layer thickness of a few nanometers were obtained.

### Example 7

Graphite was coated with titanium silicide by using CVD technology (60-100 nm layer thickness). Titanium silicide was produced in this context with silicon hydride and titanium tetrachloride in situ and the coated workpiece tempered directly subsequently at 800° C. and cooled slowly to room temperature.

What is claimed is:

1-14. (canceled)

15. A method for producing on a substrate a protective layer containing silicides and/or oxidized silicides, the method comprising:
applying one or more silicides or precursors thereof onto a substrate to form a coated substrate;
subjecting the coated substrate, without further processing, to a heat treatment at a temperature above 250° C.

16. The method according to claim 15, further comprising selecting in the step of applying at least one application method for the one or more silicides or the precursors thereof from the group consisting of PVD (physical vapor deposition), CVD (chemical vapor deposition), an electrostatic method, and screen printing.

17. The method according to claim 16, wherein the application method is cathode evaporation (sputter coating).

18. The method according to claim 15, further comprising selecting the one or more silicides from metal silicides, non-metallic silicides, and/or nitrosilicides of the general formulas
Meₓ Si_{y} (1)
wherein Me means boron, nitrogen or a metal and x is a number from 1 to 6 and y is a number from 1 to 4, wherein it is not required that x and y be integers;
Me_{x′}Si_{y′}C_{z′} (2)
wherein Me has the aforementioned meaning and x′ is a number from 1 to 3 and y′ is a number from 1 to 4, z′ is a number from 1 to 4, wherein it is not required that x′, y′ and z′ be integers;
Siₐ C_{b} (3)
wherein a is a number between 1 and 2 and b is a number between 1 and 2;
selecting the precursors from compounds of the formula
Siₑ R₂ₑ₊₂ (4)
wherein R is an organic, metallic, organometallic, or inorganic residue or a mixture thereof, and e is a number from 1 to 4;
and selecting oxidized silicides with the formulas (1) to (4) and mixtures of silicides and oxidized silicides.

19. The method according to claim 18, further comprising selecting the silicides from boron silicides, carbon-containing silicides, and nitrogen-containing silicides.

20. The method according to claim 18, further comprising selecting the silicides from the group consisting of titanium silicides (TiSi₂, Ti₅Si₃), nickel silicide (Ni₂Si), iron silicides (FeSi₂, FeSi), thallium silicide (ThSi₂), boron silicide (B₄Si), cobalt silicide (CoSi₂), platinum silicides (PtSi, Pt₂Si), manganese silicide (MnSi₂), titanium carbosilicide (Ti₃C₂Si), carbosilicide/poly-carbosilicide (CSi/poly-CSi), iridium silicide (IrSi₂), nitrosilicide (N₄Si₃), zirconium silicide (ZrSi₂), tantalum silicide (TaSi₂), vanadium silicide (V₂Si), and chromium silicide (CrSi₂).

21. The method according to claim 15, further comprising doping the silicides with lithium, sodium, magnesium, potassium, calcium, aluminum, boron, carbon, nitrogen, silicon, titanium, vanadium, zirconium, yttrium, lanthanum, nickel, manganese, cobalt, gallium, germanium, phosphorus, cadmium, arsenic, technetium, α-SiH and/or lanthanides.

22. The method according to claim 15, further comprising carrying out the heat treatment directly after coating in a temperature range between 250° C. and 1,000° C., and further comprising cooling the coated substrate after the heat treatment to room temperature.

23. The method according to claim 22, wherein the heat treatment is carried out at 250° C. to 600° C.

24. The method according to claim 22, wherein the heat treatment is carried out above 750° C.

25. The method according to claim 22, further comprising carrying out the heat treatment for a time period of one minute to 60 minutes.

26. The method according to claim 22, wherein the heat treatment is carried out for a time period of 15 minutes to 45 minutes.

27. The method according to claim 22, further comprising carrying out the heat treatment in an inert gas and replacing the inert gas entirely or partially with air during the step of cooling when a temperature range between 40° and 60° C. has been reached.

28. The method according to claim 15, further comprising selecting the substrate from silicate-containing materials, glass, glass-like materials, ceramics, precious stones, metals, noble metals, transition metals, metal oxides, plastic materials, and graphite.

29. The method according to claim 15, further comprising selecting the substrate and the silicide such that the substrate and silicide contain identical elements when the substrate is a metal or a silicate or the substrate contains a metal or a silicate.

30. The method according to claim 15, further comprising applying, before the step of applying the one or more silicides or the precursor thereof, an intermediate layer of metal with a layer thickness between 5 and 20 nm.

31. The method according to claim 30, wherein the layer thickness is between 5 and 10 nm.

32. A high-strength silicide coating obtained by coating a substrate with one or more silicides or precursors thereof according to the method of claim 15.

33. Use of the silicide coating according to claim 32 in photovoltaics as cover layers, intermediate layers, or depletion layers, in the configuration of modules in fuel-cell technology, in photoelectrochemical water splitting and as protective layer for bendable substrates/carrier materials.
